(19) United States
(12) Patent Application Publication
(10) Pub. No.: US 2026/0280500 A1
(43) Pub. Date: Sep. 17, 2026

(54) MULTIPATH INSTRUMENTATION AMPLIFIER

(71) Applicant: AMAZING MICROELECTRONIC CORP., New Taipei City (TW)

(72) Inventors: Jui-Chih CHIEN, New Taipei City (TW); Chung-Chih HUNG, New Taipei City (TW); Chung-Yu WU, New Taipei City (TW)

(73) Assignee: AMAZING MICROELECTRONIC CORP., New Taipei City (TW)

(21) Appl. No.: 19/201,102

(22) Filed: May 7, 2025

(30) Foreign Application Priority Data
Mar. 13, 2025 (TW) 114109331

(51) Int. Cl. H03F 3/38

(52) U.S. Cl. CPC H03F 3/38; H03F 2200/129

(57) ABSTRACT

A multipath instrumentation amplifier includes a low-frequency amplifier circuit and a high-frequency amplifier circuit coupled between voltage input terminals and voltage output terminals. The high-frequency amplifier circuit includes first and second amplifiers, first and second input resistors, first and second input capacitors, and first and second feedback capacitors. The inverting output terminal and the non-inverting output terminal of the first amplifier are respectively coupled to the non-inverting input terminal and the inverting input terminal of the second amplifier. The non-inverting output terminal and the inverting output terminal of the second amplifier are coupled to the voltage output terminal. The first feedback capacitor is coupled between the voltage output terminal and the inverting input terminal of the first amplifier. The second feedback capacitor is coupled between the voltage output terminal and the non-inverting input terminal of the first amplifier.

### BACKGROUND OF THE INVENTION

This application claims priority for the TW patent application no. 114109331 filed on 13 Mar. 2025, the content of which is incorporated by reference in its entirely.

### Field of the Invention

The invention relates to an instrumentation amplifier, particularly to a multipath instrumentation amplifier.

### Description of the Related Art

The instrumentation amplifier (IA) is a high-precision, low-offset, and high common-mode rejection ratio (CMRR) differential amplifier. It is mainly applied to high-precision signal processing circuits in sensor signal amplification, medical electronics, industrial measurement, and communication equipment.

The instrumentation amplifier includes multiple operational amplifiers. Generally, when the input signal of an operational amplifier is zero voltage, an undesired offset voltage still appears at the output of the operational amplifier. This voltage is typically caused by process variations in the operational amplifier. To reduce the impact of offset voltage, the instrumentation amplifier employs chopper stabilization. This technique uses high-frequency modulation to minimize the DC offset voltage and low-frequency noise in operational amplifiers (Op-Amps) or other analog circuits. A low-pass filter (LPF) is then used to filter out the modulated high-frequency components of the DC offset voltage and the low-frequency noise, ensuring a cleaner final output signal. However, chopper stabilization also introduces high-frequency ripple voltage at the amplifier's output, which can degrade the amplifier's stability and accuracy.

To overcome the abovementioned problems, the present invention provides a multipath instrumentation amplifier, so as to solve the afore-mentioned problems of the prior art.

### SUMMARY OF THE INVENTION

The invention provides a multipath instrumentation amplifier, which reduces output ripple voltage to increase stability and accuracy.

In an embodiment of the invention, a multipath instrumentation amplifier has voltage input terminals and voltage output terminals. The multipath instrument amplifier includes a low-frequency amplifier circuit and a high-frequency amplifier circuit. The low-frequency amplifier circuit and the high-frequency amplifier circuit are coupled between the voltage input terminals and the voltage output terminals. The voltage input terminals are coupled to an input voltage. The low-frequency amplifier circuit and the high-frequency amplifier circuit are configured to amplify the input voltage and transmit the amplified input voltage to the voltage output terminals. The high-frequency amplifier circuit is configured to reduce the voltage ripple across the voltage output terminals. The high-frequency amplifier circuit includes a first amplifier, a second amplifier, a first input resistor, a first input capacitor, a second input resistor, a second input capacitor, a first feedback capacitor and a second feedback capacitor. The inverting output terminal and the non-inverting output terminal of the first amplifier are respectively coupled to the non-inverting input terminal and the inverting input terminal of the second amplifier. The non-inverting output terminal and the inverting output terminal of the second amplifier are coupled to the voltage output terminals. The first input resistor and the first input capacitor are coupled in series between a first reference voltage and the voltage input terminal. A node between the first input resistor and the first input capacitor is coupled to the non-inverting input terminal of the first amplifier. The second input resistor and the second input capacitor are coupled in series between the first reference voltage and the voltage input terminal. A node between the second input resistor and the second input capacitor is coupled to the inverting input terminal of the first amplifier. The first feedback capacitor is coupled between the voltage output terminal and the inverting input terminal of the first amplifier. The second feedback capacitor is coupled between the voltage output terminal and the non-inverting input terminal of the second amplifier.

In an embodiment of the invention, the low-frequency amplifier circuit includes a third amplifier, a first chopper, a third input capacitor, a fourth input capacitor, a second chopper, a fourth amplifier, a fifth amplifier, a third chopper, a third feedback capacitor, a first feedback resistor, a fourth feedback capacitor and a second feedback resistor. The input terminal of the first chopper is coupled to the voltage input terminal. The output terminals of the first chopper are respectively coupled to the non-inverting input terminal and the inverting input terminal of the third amplifier through the third input capacitor and the fourth input capacitor. The input terminals of the second chopper are respectively coupled to the inverting output terminal and the non-inverting output terminal of the third amplifier. The non-inverting input terminal and the inverting input terminal of the fourth amplifier are coupled to the output terminals of the second chopper. The non-inverting input terminal and the inverting input terminal of the fifth amplifier are respectively coupled to the inverting output terminal and the non-inverting output terminal of the fourth amplifier. The inverting output terminal and the non-inverting output terminal of the fifth amplifier are respectively coupled to the non-inverting input terminal and the inverting input terminal of the second amplifier. The third chopper has a first input terminal and a second input terminal. The output terminals of the third chopper are coupled to the voltage output terminals. The third feedback capacitor and the first feedback resistor are coupled in parallel with each other and coupled between the first input terminal of the third chopper and the inverting input terminal of the third amplifier. The fourth feedback capacitor and the second feedback resistor are coupled in parallel to each other and coupled between the second input terminal of the third chopper and the non-inverting input terminal of the third amplifier.

In an embodiment of the invention, the multipath instrumentation amplifier further includes a resistor-capacitor (RC) circuit coupled to the inverting input terminals, the non-inverting input terminals, the inverting output terminals, and the non-inverting output terminals of the fourth amplifier and the second amplifier and configured to perform frequency compensation on the low-frequency amplifier circuit and the high-frequency amplifier circuit.

In an embodiment of the invention, the resistor-capacitor circuit is a low-pass filter.

In an embodiment of the invention, the resistor-capacitor circuit includes a first compensation capacitor, a second compensation capacitor, a third compensation capacitor, a first compensation resistor, a fourth compensation capacitor, a second compensation resistor, a fifth compensation capacitor and a sixth compensation capacitor. The first compensation capacitor is coupled between the non-inverting output terminal of the second amplifier and the inverting input terminal of the fourth amplifier. The second compensation capacitor is coupled between the inverting output terminal of the second amplifier and the non-inverting input terminal of the fourth amplifier. The third compensation capacitor and the first compensation resistor are coupled in series with each other and coupled between the inverting output terminal and the non-inverting input terminal of the fourth amplifier. The fourth compensation capacitor and the second compensation resistor are coupled in series with each other and coupled between the non-inverting output terminal and the inverting input terminal of the fourth amplifier. The fifth compensation capacitor is coupled between the non-inverting input terminal and the inverting output terminal of the second amplifier. The sixth compensation capacitor is coupled between the inverting input terminal and the non-inverting output terminal of the second amplifier.

In an embodiment of the invention, the multipath instrumentation amplifier further includes a first loop capacitor and a second loop capacitor. One terminal of the first loop capacitor is coupled to a node between the first chopper and the fourth input capacitor and another terminal of the first loop capacitor is coupled to the second input terminal of the third chopper. One terminal of the second loop capacitor is coupled to a node between the first chopper and the third input capacitor and another terminal of the second loop capacitor is coupled to the first input terminal of the third chopper.

In an embodiment of the invention, the multipath instrumentation amplifier further includes a third loop capacitor and a fourth loop capacitor. One terminal of the third loop capacitor is coupled to a node between the voltage input terminal and the first input capacitor and another terminal of t he third loop capacitor is coupled to a node between the voltage output terminal and the inverting output terminal of the second amplifier. One terminal of the fourth loop capacitor is coupled to a node between the voltage input terminal and the second input capacitor and another terminal of the fourth loop capacitor is coupled to a node between the voltage output terminal and the non-inverting output terminal of the second amplifier.

In an embodiment of the invention, the multipath instrumentation amplifier further includes a first capacitor, a second capacitor, a first loop chopper, a first loop amplifier, a second loop amplifier, a third capacitor and a fourth capacitor. The input terminals of the first loop chopper are respectively coupled to the inverting input terminal and the non-inverting input terminal of the fifth amplifier through the first capacitor and the second capacitor. The non-inverting input terminal and the inverting input terminal of the first loop amplifier are coupled to the output terminals of the first loop chopper. The non-inverting input terminal and the inverting input terminal of the second loop amplifier are respectively coupled to the inverting output terminal and the non-inverting output terminal of the first loop amplifier. The non-inverting output terminal and the inverting output terminal of the second loop amplifier are respectively coupled to the inverting output terminal and the non-inverting output terminal of the third amplifier. The third capacitor is coupled between the non-inverting input terminal and the inverting output terminal of the first loop amplifier. The fourth capacitor is coupled between the inverting input terminal and the non-inverting output terminal of the first loop amplifier.

In an embodiment of the invention, the multipath instrumentation amplifier further includes a first auto-zeroing capacitor, a first switch, a second auto-zeroing capacitor, a second switch, a third loop amplifier, a fourth loop amplifier, a third switch, a fourth switch, a fifth capacitor, a sixth capacitor, and a fifth loop amplifier. The first switch couples the first auto-zeroing capacitor to the inverting input terminal of the first loop amplifier or a second reference voltage. The second switch couples the second auto-zeroing capacitor to the non-inverting input terminal of the first loop amplifier or the second reference voltage. The non-inverting input terminal of the third loop amplifier is coupled to the first switch through the first auto-zeroing capacitor. The inverting input terminal of the third loop amplifier is coupled to the second switch through the second auto-zeroing capacitor. The third switch couples the inverting output terminal of the third loop amplifier to the non-inverting input terminal of the fourth loop amplifier or the non-inverting input terminal of the third loop amplifier. The fourth switch couples the non-inverting output terminal of the third loop amplifier to the inverting input terminal of the fourth loop amplifier or the inverting input terminal of the third loop amplifier. The fifth capacitor is coupled between the inverting output terminal and the non-inverting input terminal of the fourth loop amplifier. The sixth capacitor is coupled between the non-inverting output terminal and the inverting input terminal of the fourth loop amplifier. The non-inverting input terminal and the inverting input terminal of the fifth loop amplifier are respectively coupled to the inverting output terminal and the non-inverting output terminal of the fourth loop amplifier. The inverting output terminal and the non-inverting output terminal of the fifth loop amplifier are respectively coupled to the non-inverting input terminal and the inverting input terminal of the second loop amplifier.

In an embodiment of the invention, the multi-path instrumentation amplifier further includes a first auto-zeroing capacitor, a first switch, a second auto-zeroing capacitor, a second switch, a third loop amplifier, a fourth loop amplifier, a third switch, a fourth switch and a fifth capacitor. The first switch couples the first auto-zeroing capacitor to the inverting input terminal of the first loop amplifier or a second reference voltage. The second switch couples the second auto-zeroing capacitor to the non-inverting input terminal of the first loop amplifier or the second reference voltage. The non-inverting input terminal of the third loop amplifier is coupled to the first switch through the first auto-zeroing capacitor. The inverting input terminal of the third loop amplifier is coupled to the second switch through the second auto-zeroing capacitor. The inverting output terminal and the non-inverting output terminal of the fourth loop amplifier are respectively coupled to the inverting input terminal and the non-inverting input terminal of the second loop amplifier. The third switch couples the inverting output terminal of the third loop amplifier to the non-inverting input terminal of the fourth loop amplifier or the non-inverting input terminal of the third loop amplifier. The fourth switch couples the non-inverting output terminal of the third loop amplifier to the inverting input terminal of the fourth loop amplifier or the inverting input terminal of the third loop amplifier. The fifth capacitor is coupled between the inverting input terminal and the non-inverting input terminal of the fourth loop amplifier.

In an embodiment of the invention, the multipath instrumentation amplifier further includes a third loop amplifier, a second loop chopper, a fourth loop amplifier, a fifth capacitor, a sixth capacitor and a fifth loop amplifier. The inverting input terminal of the third loop amplifier is coupled to a node between the first capacitor and the first loop chopper. The non-inverting input terminal of the third loop amplifier is coupled to a node between the second capacitor and the first loop chopper. The non-inverting input terminal and the inverting input terminal of the fourth loop amplifier are respectively coupled to the inverting output terminal and the non-inverting output terminal of the third loop amplifier through the second loop chopper. The fifth capacitor is coupled between the inverting output terminal and the non-inverting input terminal of the fourth loop amplifier. The sixth capacitor is coupled between the non-inverting output terminal and the inverting input terminal of the fourth loop amplifier. The non-inverting input terminal and the inverting input terminal of the fifth loop amplifier are respectively coupled to the inverting output terminal and the non-inverting output terminal of the fourth loop amplifier. The inverting output terminal and the non-inverting output terminal of the fifth loop amplifier are respectively coupled to the non-inverting input terminal and the inverting input terminal of the second loop amplifier.

In an embodiment of the invention, the multipath instrumentation amplifier further includes a first nested chopper and a second nested chopper. One terminal of the third capacitor is coupled to the non-inverting input terminal of the first loop amplifier through the first nested chopper. Another terminal of the third capacitor is coupled to the inverting output terminal of the first loop amplifier through the second nested chopper. One terminal of the fourth capacitor is coupled to the inverting input terminal of the first loop amplifier through the first nested chopper and another terminal of the fourth capacitor is coupled to the non-inverting output terminal of the first loop amplifier through the second nested chopper.

In an embodiment of the invention, the multipath instrumentation amplifier further includes a first capacitor, a second capacitor, a first buffer, a first loop chopper, a second buffer, a third capacitor and a loop amplifier. The inverting input terminal and the non-inverting input terminal of the first buffer are respectively coupled to the inverting input terminal and the non-inverting input terminal of the fifth amplifier through the first capacitor and the second capacitor. The input terminals of the first loop chopper are respectively coupled to the non-inverting output terminal and the inverting output terminal of the first buffer. The inverting input terminal and the non-inverting input terminal of the second buffer are respectively coupled to the output terminals of the first loop chopper. The third capacitor is coupled between the non-inverting output terminal and the inverting output terminal of the second buffer. The non-inverting input terminal and the inverting input terminal of the loop amplifier are respectively coupled to the non-inverting output terminal and the inverting output terminal of the second buffer. The non-inverting output terminal and the inverting output terminal of the loop amplifier are respectively coupled to the non-inverting output terminal and the inverting output terminal of the third amplifier.

In an embodiment of the invention, the multipath instrumentation amplifier further includes a buffer whose inverting input terminal and non-inverting input terminal are respectively coupled to the first capacitor and the second capacitor. The non-inverting output terminal and the inverting output terminal of the buffer are respectively coupled to the input terminals of the first loop chopper.

In an embodiment of the invention, the multipath instrumentation amplifier further includes a fourth chopper whose input terminals are respectively coupled to the non-inverting input terminal and the inverting input terminal of the third amplifier. The output terminals of the fourth chopper are respectively coupled to the non-inverting input terminal and the inverting input terminal of the first amplifier.

To sum up, the multipath instrumentation amplifier employs the high-frequency amplifier circuit and uses the capacitors to form feedback paths and reduce the voltage ripple across the voltage output terminals, thereby increasing stability and accuracy.

Below, the embodiments are described in detail in cooperation with the drawings to make easily understood the technical contents, characteristics and accomplishments of the invention.

### BRIEF DESCRIPTION OF THE DRAWINGS

FIG. 1 is a diagram schematically illustrating a multipath instrumentation amplifier according to a first embodiment of the invention;

FIG. 2 is a diagram schematically illustrating a chopper according to an embodiment of the invention;

FIG. 3 is a diagram schematically illustrating the Bode magnitude plots of a low-frequency amplifier circuit, a high-frequency amplifier circuit, and a multipath instrumentation amplifier according to an embodiment of the invention;

FIG. 4 is a diagram schematically illustrating a ripple reduction loop according to a first embodiment of the invention;

FIG. 5 is a diagram schematically illustrating an offset compensation loop according to a first embodiment of the invention;

FIG. 6 is a diagram schematically illustrating an offset compensation loop according to a second embodiment of the invention;

FIG. 7 is a diagram schematically illustrating an offset compensation loop according to a third embodiment of the invention;

FIG. 8 is a diagram schematically illustrating a ripple reduction loop according to a second embodiment of the invention;

FIG. 9 is a diagram schematically illustrating a ripple reduction loop according to a third embodiment of the invention;

FIG. 10 is a diagram schematically illustrating a ripple reduction loop according to a fourth embodiment of the invention; and

FIG. 11 is a diagram schematically illustrating a multipath instrumentation amplifier according to a second embodiment of the invention.

### DETAILED DESCRIPTION OF THE INVENTION

Reference will now be made in detail to embodiments illustrated in the accompanying drawings. Wherever possible, the same reference numbers are used in the drawings and the description to refer to the same or like parts. In the drawings, the shape and thickness may be exaggerated for clarity and convenience. This description will be directed in particular to elements forming part of, or cooperating more directly with, methods and apparatus in accordance with the present disclosure. It is to be understood that elements not specifically shown or described may take various forms well known to those skilled in the art. Many alternatives and modifications will be apparent to those skilled in the art, once informed by the present disclosure.

Unless otherwise specified, some conditional sentences or words, such as “can”, “could”, “might”, or “may”, usually attempt to express what the embodiment in the invention has, but it can also be interpreted as a feature, element, or step that may not be needed. In other embodiments, these features, elements, or steps may not be required.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

Certain terms are used throughout the description and the claims to refer to particular components. One skilled in the art appreciates that a component may be referred to using different names. This disclosure does not intend to distinguish between components that differ in name but not in function. In the description and in the claims, the term “comprise” is used in an open-ended fashion, and thus should be interpreted to mean “include, but not limited to.” The phrases “be coupled to,” “couples to,” and “coupling to” are intended to encompass any indirect or direct connection. Accordingly, if this disclosure mentions that a first device is coupled with a second device, it means that the first device may be directly or indirectly connected to the second device through electrical connections, wireless communications, optical communications, or other signal connections with/without other intermediate devices or connection means.

The invention is particularly described with the following examples which are only for instance. Those skilled in the art will readily observe that numerous modifications and alterations of the device and method may be made while retaining the teachings of the invention. Accordingly, the following disclosure should be construed as limited only by the metes and bounds of the appended claims. In the whole patent application and the claims, except for clearly described content, the meaning of the articles “a” and “the” includes the meaning of “one or at least one” of the elements or components. Moreover, in the whole patent application and the claims, except that the plurality can be excluded obviously according to the context, the singular articles also contain the description for the plurality of elements or components. In the entire specification and claims, unless the contents clearly specify the meaning of some terms, the meaning of the article “wherein” includes the meaning of the articles “wherein” and “whereon”. The meanings of every term used in the present claims and specification refer to a usual meaning known to one skilled in the art unless the meaning is additionally annotated. Some terms used to describe the invention will be discussed to guide practitioners about the invention. The examples in the present specification do not limit the claimed scope of the invention.

In the following description, a multipath instrumentation amplifier will be described. The multipath instrumentation amplifier employs a high-frequency amplifier circuit and uses capacitors to form feedback paths and reduce the voltage ripple across the voltage output terminals, thereby increasing stability and accuracy.

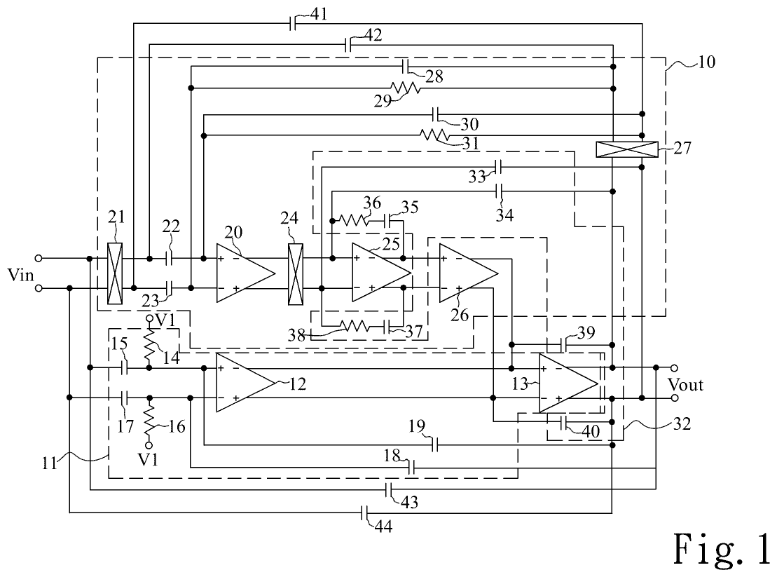

FIG. 1 is a diagram schematically illustrating a multipath instrumentation amplifier according to a first embodiment of the invention. Please refer to FIG. 1. The multipath instrumentation amplifier will be introduced as follows. The multipath instrumentation amplifier has voltage input terminals and voltage output terminals. The multipath instrumentation amplifier includes a low-frequency amplifier circuit 10 and a high-frequency amplifier circuit 11 coupled between the voltage input terminals and the voltage output terminals. The high-frequency amplifier circuit 11 includes a first amplifier 12, a second amplifier 13, a first input resistor 14, a first input capacitor 15, a second input resistor 16, a second input capacitor 17, a first feedback capacitor 18, and a second feedback capacitor 19. The first amplifier 12 and the second amplifier 13 may be, but not limited to, transconductance amplifiers. The inverting output terminal and the non-inverting output terminal of the first amplifier 12 are respectively coupled to the non-inverting input terminal and the inverting input terminal of the second amplifier 13. The non-inverting output terminal and the inverting output terminal of the second amplifier 13 are coupled to the voltage output terminal. The first input resistor 14 and the first input capacitor 15 are coupled in series between a first reference voltage V1 and the voltage input terminal. A node between the first input resistor 14 and the first input capacitor 15 is coupled to the non-inverting input terminal of the first amplifier 12. The second input resistor 16 and the second input capacitor 17 are coupled in series between the first reference voltage V1 and the voltage input terminal. A node between the second input resistor 16 and the second input capacitor 17 is coupled to the inverting input terminal of the first amplifier 12. The first feedback capacitor 18 is coupled between the voltage output terminal and the inverting input terminal of the first amplifier 12. The second feedback capacitor 19 is coupled between the voltage output terminal and the non-inverting input terminal of the first amplifier 12.

The low-frequency amplifier circuit may include, but is not limited to, a third amplifier 20, a first chopper 21, a third input capacitor 22, a fourth input capacitor 23, a second chopper 24, a fourth amplifier 25, a fifth amplifier 26, a third chopper 27, a third feedback capacitor 28, a first feedback resistor 29, a fourth feedback capacitor 30, and a second feedback resistor 31. The fourth amplifier 25 and the fifth amplifier 26 may be, but not limited to, transconductance amplifiers. The input terminals of the first chopper 21 are coupled to the voltage input terminal. The output terminals of the first chopper 21 are respectively coupled to the non-inverting input terminal and the inverting input terminal of the third amplifier 20 through the third input capacitor 22 and the fourth input capacitor 23. The input terminals of the second chopper 24 are respectively coupled to the inverting output terminal and the non-inverting output terminal of the third amplifier 20. The non-inverting input terminal and the inverting input terminal of the fourth amplifier 25 are coupled to the output terminals of the second chopper 24. The non-inverting input terminal and the inverting input terminal of the fifth amplifier 26 are respectively coupled to the inverting output terminal and the non-inverting output terminal of the fourth amplifier 25. The inverting output terminal and the non-inverting output terminal of the fifth amplifier 26 are respectively coupled to the non-inverting input terminal and the inverting input terminal of the second amplifier 13. The third chopper 27 has a first input terminal and a second input terminal. The output terminals of the third chopper 27 are coupled to the voltage output terminals. The third feedback capacitor 28 and the first feedback resistor 29 are coupled in parallel to each other and coupled between the first input terminal of the third chopper 27 and the inverting input terminal of the third amplifier 20. The fourth feedback capacitor 30 and the second feedback resistor 31 are coupled in parallel to each other and are coupled between the second input terminal of the third chopper 27 and the non-inverting input terminal of the third amplifier 20.

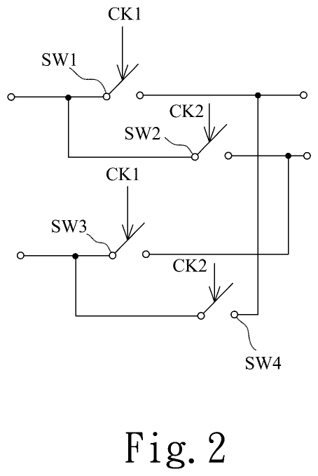

FIG. 2 is a diagram schematically illustrating a chopper according to an embodiment of the invention. The chopper used in the multipath instrumentation amplifier is shown in FIG. 2. The chopper has two input terminals and two output terminals and includes a first electronic switch SW1, a second electronic switch SW2, a third electronic switch SW3, and a fourth electronic switch SW4. The control terminals of the first electronic switch SW1 and the third electronic switch SW3 are coupled to a first clock signal CK1. The control terminals of the second electronic switch SW2 and the fourth electronic switch SW4 are coupled to a second clock signal CK2. The first clock signal CK1 and the second clock signal CK2 have opposite phases and the same frequency. One terminal of the first electronic switch SW1 is coupled to an input terminal and one terminal of the second electronic switch SW2 and another end of the first electronic switch SW1 is coupled to an output terminal and one terminal of the fourth electronic switch SW4. Another terminal of the second electronic switch SW2 is coupled to another output terminal and one terminal of the third electronic switch SW3. Another terminal of the third electronic switch SW3 is coupled to another input terminal and another terminal of the fourth electronic switch SW4. The frequencies f_{CH} corresponding to all choppers of the multipath instrumentation amplifier are the same.

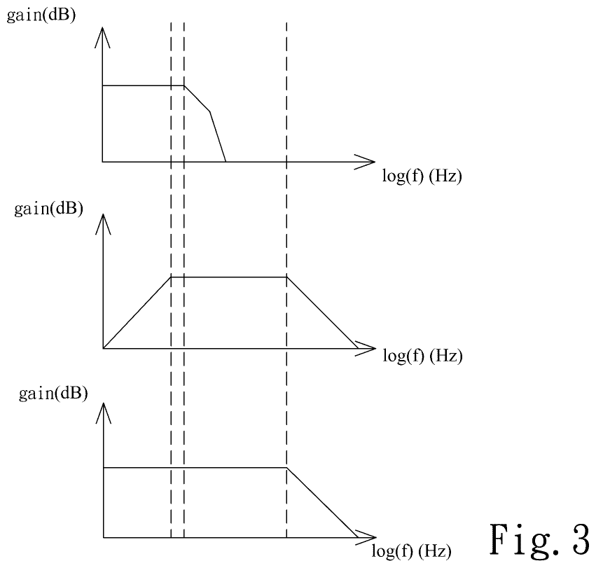

FIG. 3 is a diagram schematically illustrating the Bode magnitude plots of a low-frequency amplifier circuit, a high-frequency amplifier circuit, and a multipath instrumentation amplifier according to an embodiment of the invention. Please refer to FIG. 1 and FIG. 3. The voltage input terminals are coupled to an input voltage Vin. The low-frequency amplifier circuit 10 and the high-frequency amplifier circuit 11 amplify the input voltage Vin and transmit the amplified input voltage Vin to the voltage output terminals to generate an output voltage Vout. The high-frequency amplifier circuit 11 uses the first feedback capacitor 18 and the second feedback capacitor 19 to form a negative feedback path to reduce the voltage ripples across the voltage output terminals, thereby increasing the stability and accuracy of the multipath instrumentation amplifier. In FIG. 3, the upper inset represents the low-frequency amplifier circuit 10, the middle inset represents the high-frequency amplifier circuit 11, the lower inset represents the multipath instrumentation amplifier, and f represents the frequency. The gain of the multipath instrumentation amplifier is determined by the capacitance ratio of the first input capacitor 15, the second input capacitor 17, the third input capacitor 22, the fourth input capacitor 23, the first feedback capacitor 18, the second feedback capacitor 19, the third feedback capacitor 28, and the fourth feedback capacitor 30. The frequency response of the low-frequency amplifier circuit 10 starts decreasing at low frequencies. If the cutoff frequency of the high-frequency amplifier circuit 11 is lower than the −3 dB frequency of the low-frequency amplifier circuit 10, the overall frequency response will remain flat. This is because the function of the low-frequency amplifier circuit 10 will be taken over by the function of the high-frequency amplifier circuit 11 when the frequency response of the low-frequency amplifier circuit 10 starts decreasing. In other words, the high-frequency amplifier circuit 11 is a feedforward path for compensating the bandwidth limitation in the low-frequency amplifier circuit 10. Finally, the overall frequency response will follow the high-frequency amplifier circuit 11 at high frequencies, determining the overall −3 dB bandwidth and achieving high bandwidth chopper amplifier. Although the overall bandwidth can be enhanced by the high-frequency amplifier circuit 11, the flicker noise and offset in the high-frequency amplifier circuit 11 must be removed. Therefore, additional feedback paths exist between the high-frequency amplifier circuit 11 and the low-frequency amplifier circuit 10 to establish an offset-stabilized (OS) circuit. The offset voltage of the first amplifier 12 at output nodes is coupled to the low-frequency amplifier circuit 10 by the third chopper 27, the third feedback capacitor 28, the first feedback resistor 29, the fourth feedback capacitor 30, and the second feedback resistor 31. Then, the offset voltage is fed back to the auxiliary input path of the first amplifier 12, namely the fifth amplifier 26. Due to negative feedback, the offset voltage of the first amplifier 12 will be stabilized by the gains of the third amplifier 20, the fourth amplifier 25, and the fifth amplifier 26. The noise of the high-frequency amplifier circuit 11 is suppressed by the same principle, too.

Although the frequency response of the multipath instrumentation amplifier is determined by the high-frequency amplifier circuit 11, the low-frequency amplifier circuit 10 should maintain stability before being taken over by the high-frequency amplifier circuit 11. In order to achieve stability compensation and ripple suppression, the multipath instrumentation amplifier may further include a resistor-capacitor (RC) circuit 32 coupled to the inverting input terminals, the non-inverting input terminals, the inverting output terminals, and the non-inverting output terminals of the fourth amplifier 25 and the second amplifier 13. The RC circuit 32 performs frequency compensation on the low-frequency amplifier circuit 10 and the high-frequency amplifier circuit 11. The RC circuit 32 may be, but not limited to, a low-pass filter. In some embodiments of the invention, The RC circuit 32 may include, but is not limited to, a first compensation capacitor 33, a second compensation capacitor 34, a third compensation capacitor 35, a first compensation resistor 36, a fourth compensation capacitor 37, a second compensation resistor 38, a fifth compensation capacitor 39, and a sixth compensation capacitor 40. The first compensation capacitor 33 is coupled between the non-inverting output terminal of the second amplifier 13 and the inverting input terminal of the fourth amplifier 25. The second compensation capacitor 34 is coupled between the inverting output terminal of the second amplifier 13 and the non-inverting input terminal of the fourth amplifier 25. The third compensation capacitor 35 and the first compensation resistor 36 are coupled to each other in series and coupled between the inverting output terminal and the non-inverting input terminal of the fourth amplifier 25. The fourth compensation capacitor 37 and the second compensation resistor 38 are coupled in series to each other and coupled between the non-inverting output terminal and the inverting input terminal of the fourth amplifier 25. The fifth compensation capacitor 39 is coupled between the non-inverting input terminal and the inverting output terminal of the second amplifier 13. The sixth compensation capacitor 40 is coupled between the inverting input terminal and the non-inverting output terminal of the second amplifier 13.

For the application to amplify a voltage signal, the input impedance of the multipath instrumentation amplifier should be high enough to input the signal from the source. Unfortunately, although the low-frequency amplifier circuit 10 can amplify DC signals, DC impedance will be decreased by choppers and input capacitors. In addition, the input capacitors will lead to a low impedance at high frequency for the high-frequency amplifier circuit 11. To solve the problems, the multipath instrumentation amplifier may further include a first loop capacitor 41, a second loop capacitor 42, a third loop capacitor 43, and a fourth loop capacitor 44.

The first loop capacitor 41 and the second loop capacitor 42 are used to eliminate the non-ideal input current introduced by the first chopper 21, the third input capacitor 22, and the fourth capacitor 23 at low frequencies. One terminal of the first loop capacitor 41 is coupled to a node between the first chopper 21 and the fourth input capacitor 23 and another terminal of the first loop capacitor 41 is coupled to the second input terminal of the third chopper 27. One terminal of the second loop capacitor 42 is coupled to a node between the first chopper 21 and the third input capacitor 22 and another terminal of the second loop capacitor 42 is coupled to the first input terminal of the third chopper 27.

The third loop capacitor 43 and the fourth loop capacitor 44 are used to eliminate the non-ideal input current introduced by the first input capacitor 15 and the second input capacitor 17 at high frequencies. One terminal of the third loop capacitor 43 is coupled to a node between the voltage input terminal and the first input capacitor 15 and another terminal of the third loop capacitor 43 is coupled to a node between the voltage output terminal and the inverting output terminal of the second amplifier 13. One terminal of the fourth loop capacitor 44 is coupled to a node between the voltage input terminal and the second input capacitor 17 and another terminal of the fourth loop capacitor 44 is coupled to a node between the voltage output terminal and the non-inverting output terminal of the second amplifier 13.

Assume that the capacitances of the first input capacitor 15, the second input capacitor 17, the third input capacitor 22, and the fourth input capacitor 23 are the same and represented by C_{IN}. Assume that the capacitances of the first loop capacitor 41, the second loop capacitor 42, the third loop capacitor 43, and the fourth loop capacitor 44 are the same and represented by C_{PFL}. At low frequencies, Zin=1/{2f_{CH}[C_{IN}-C_{PFL} (A_{CL,CCCIA}−1)]} due to the third input capacitor 22, the fourth input capacitor 23, the first loop capacitor 41, and the second loop capacitor 42. At high frequencies, Zin=1/{[C_{IN}-C_{PFL} (A_{CL,CCIA}−1)]} due to the first input capacitor 15, the second input capacitor 17, the third loop capacitor 43, and the fourth loop capacitor 44. Zin represents the input impedance of the multipath instrumentation amplifier, A_{CL,CCCIA} represents the closed-loop gain of the low-frequency amplifier circuit 10, A_{CL, CCIA} represents the closed-loop gain of the high-frequency amplifier circuit 11, and A_{MCCCIA} represents the gain of the multipath instrumentation amplifier. Therefore, C_{PFL}=C_{IN}/(A_{MCCCIA}−1) when Zin is infinite and A_{CL,CCCIA}=A_{CL,CCIA}=A_{MCCCIA}.

The ripple reduction is provided by the high-frequency amplifier circuit 11. Thus, the high-frequency amplifier circuit 11 is also called an autonomous ripple reduction loop. Because a chopper modulation is employed in the low-frequency amplifier circuit 10, the chopping ripple will exist at the voltage output terminal. The chopping ripple at the voltage output terminal is coupled into the high-frequency amplifier circuit 11 and then fed back to the voltage output terminal by the first amplifier 12 and the second amplifier 13. The reason for the chopping ripple not being coupled into the low-frequency amplifier circuit 10 is third chopper 27. The third chopper 27 will modulate the chopping ripple back to DC, and the DC signal will be blocked by the infinite impedance of third feedback capacitor 28 and the fourth feedback capacitor 30 at DC. Therefore, the chopping ripple will be coupled into the high-frequency amplifier circuit 11 only, letting the high-frequency amplifier circuit 11 work as the ripple reduction loop of the low-frequency amplifier circuit 10. The advantages of the autonomous ripple reduction loop are not only that it achieves ripple reduction functionality without adding additional circuitry but also that it suppresses the non-ideal effects of noise and offset in the ripple reduction loop by the offset stabilized circuit. In addition, the multipath instrumentation amplifier can use the fundamental principles of capacitors and the modulation techniques of choppers to distinguish the feedback paths of different signals clearly, such as output ripple will follow the path of the autonomous ripple reduction loop and the offset voltage of the first amplifier 12 will follows the path of the offset stabilized circuit. Assume that L represents the gain of the autonomous ripple reduction loop, Ro1 and Ro2 are respectively the output resistance values of the first amplifier 12 and the second amplifier 13, Gm1 and Gm2 are respectively the transconductances of the first amplifier 12 and the second amplifier 13, and the capacitances of the first feedback capacitor 18 and the second feedback capacitor 19 are the same and represented by C_{FB}. C_{IN}>>C_{FB}. Due to the first feedback capacitor 18, the second feedback capacitor 19, the first input capacitor 15, and the second input capacitor 17, A_{CL,CCIA}=C_{IN}/C_{FB}. Due to the first amplifier 12 and the second amplifier 13, A_{OL,CCIA}=Gm1×Ro1×Gm2×Ro2, where A_{OL,CCIA} represents the open-loop gain of the high-frequency amplifier circuit 11. Due to the first feedback capacitor 18, the second feedback capacitor 19, the first input capacitor 15, the second input capacitor 17, the first amplifier 12, and the second amplifier 13, L≈C_{FB}×Gm1×Ro1×Gm2×Ro2/(C_{IN}+C_{FB})≈C_{FB}×Gm1×Ro1×Gm2×Ro2/C_{IN}=A_{OL,CCIA}/A_{CL,CCIA}. Therefore, L is directly proportional to A_{OL,CCIA}.

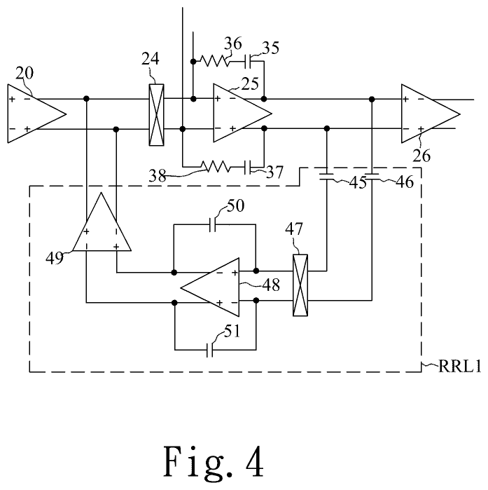

FIG. 4 is a diagram schematically illustrating a ripple reduction loop according to a first embodiment of the invention. Please refer to FIG. 4. When the frequency response of the amplifier has a notch, the notch can reduce the chopping ripple. However, the notch in frequency response will lead to an undesired ringing in step response. To solve the problem, the multipath instrumentation amplifier only inserts a ripple reduction loop RRL1 in the low-frequency amplifier circuit 10. Therefore, the overall frequency response of the multipath instrumentation amplifier will not have a notch, and the ripple reduction loop RRL1 also retains the function of suppressing the chopping ripple. The ripple reduction loop RRL1 includes a first capacitor 45, a second capacitor 46, a first loop chopper 47, a first loop amplifier 48, a second loop amplifier 49, a third capacitor 50, and a fourth capacitor 51. The first loop amplifier 48 and the second loop amplifier 49 may be, but not limited to, transconductance amplifiers. The input terminals of the first loop chopper 47 are respectively coupled to the inverting input terminal and the non-inverting input terminal of the fifth amplifier 26 through the first capacitor 45 and the second capacitor 46. The non-inverting input terminal and the inverting input terminal of the first loop amplifier 48 are coupled to the output terminals of the first loop chopper 47. The non-inverting input terminal and the inverting input terminal of the second loop amplifier 49 are respectively coupled to the inverting output terminal and the non-inverting output terminal of the first loop amplifier 48. The non-inverting output terminal and the inverting output terminal of the second loop amplifier 49 are respectively coupled to the inverting output terminal and the non-inverting output terminal of the third amplifier 20. The third capacitor 50 is coupled between the non-inverting input terminal and the inverting output terminal of the first loop amplifier 48. The fourth capacitor 51 is coupled between the inverting input terminal and the non-inverting output terminal of the first loop amplifier 48.

However, the offset voltage of the ripple reduction loop RRL1 will generate additional residual ripples across the voltage output terminals that cannot be suppressed. In order to solve this problem, an offset compensation loop is designed.

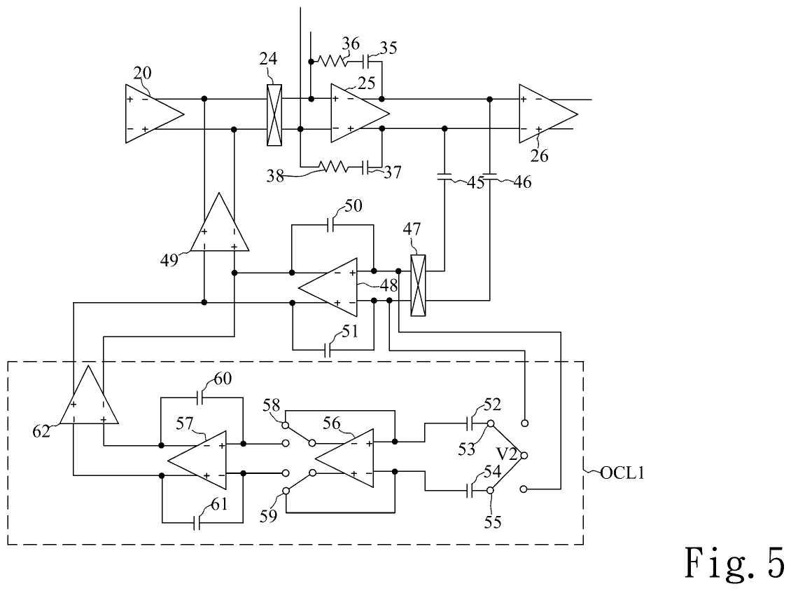

FIG. 5 is a diagram schematically illustrating an offset compensation loop according to a first embodiment of the invention. Please refer to FIG. 5. The multipath instrumentation amplifier further includes an offset compensation loop OCL1. The offset compensation loop OCL1 includes a first auto-zeroing capacitor 52, a first switch 53, a second auto-zeroing capacitor 54, a second switch 55, a third loop amplifier 56, a fourth loop amplifier 57, a third switch 58, a fourth switch 59, a fifth capacitor 60, a sixth capacitor 61, and a fifth loop amplifier 62. The third loop amplifier 56, the fourth loop amplifier 57, and the fifth loop amplifier 62 may be, but not limited to, transconductance amplifiers. The first switch 53 couples the first auto-zeroing capacitor 52 to the inverting input terminal of the first loop amplifier 48 or a second reference voltage V2. The second switch 55 couples the second auto-zeroing capacitor 54 to the non-inverting input terminal of the first loop amplifier 48 or the second reference voltage V2. The non-inverting input terminal of the third loop amplifier 56 is coupled to the first switch 53 through the first auto-zeroing capacitor 52. The inverting input terminal of the third loop amplifier 56 is coupled to the second switch 55 through the second auto-zeroing capacitor 54. The third switch 58 couples the inverting output terminal of the third loop amplifier 56 to the non-inverting input terminal of the fourth loop amplifier 57 or the non-inverting input terminal of the third loop amplifier 56. The fourth switch 59 couples the non-inverting output terminal of the third loop amplifier 56 to the inverting input terminal of the fourth loop amplifier 57 or the inverting input terminal of the third loop amplifier 56. The fifth capacitor 60 is coupled between the inverting output terminal and the non-inverting input terminal of the fourth loop amplifier 57. The sixth capacitor 61 is coupled between the non-inverting output terminal and the inverting input terminal of the fourth loop amplifier 57. The non-inverting input terminal and the inverting input terminal of the fifth loop amplifier 62 are respectively coupled to the inverting output terminal and the non-inverting output terminal of the fourth loop amplifier 57. The inverting output terminal and the non-inverting output terminal of the fifth loop amplifier 62 are respectively coupled to the non-inverting input terminal and the inverting input terminal of the second loop amplifier 49.

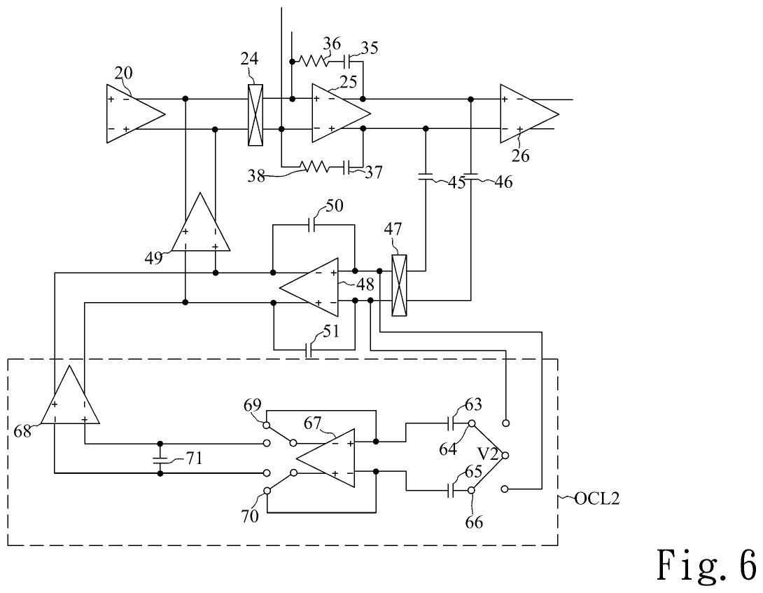

FIG. 6 is a diagram schematically illustrating an offset compensation loop according to a second embodiment of the invention. Please refer to FIG. 6. The multipath instrumentation amplifier further includes an offset compensation loop OCL2. The offset compensation loop OCL2 includes a first auto-zeroing capacitor 63, a first switch 64, a second auto-zeroing capacitor 65, a second switch 66, a third loop amplifier 67, a fourth loop amplifier 68, a third switch 69, a fourth switch 70, and a fifth capacitor 71. The third loop amplifier 67 and the fourth loop amplifier 68 may be, but not limited to, transconductance amplifiers. The first switch 64 couples the first auto-zeroing capacitor 63 to the inverting input terminal of the first loop amplifier 48 or a second reference voltage V2. The second switch 66 couples the second auto-zeroing capacitor 65 to the non-inverting input terminal of the first loop amplifier 48 or the second reference voltage V2. The non-inverting input terminal of the third loop amplifier 67 is coupled to the first switch 64 through the first auto-zeroing capacitor 63. The inverting input terminal of the third loop amplifier 67 is coupled to the second switch 66 through the second auto-zeroing capacitor 65. The inverting output terminal and the non-inverting output terminal of the fourth loop amplifier 68 are respectively coupled to the inverting input terminal and the non-inverting input terminal of the second loop amplifier 49. The third switch 69 couples the inverting output terminal of the third loop amplifier 67 to the non-inverting input terminal of the fourth loop amplifier 68 or the non-inverting input terminal of the third loop amplifier 67. The fourth switch 70 couples the non-inverting output terminal of the third loop amplifier 67 to the inverting input terminal of the fourth loop amplifier 68 or the inverting input terminal of the third loop amplifier 67. The fifth capacitor 71 is coupled between the inverting input terminal and the non-inverting input terminal of the fourth loop amplifier 68.

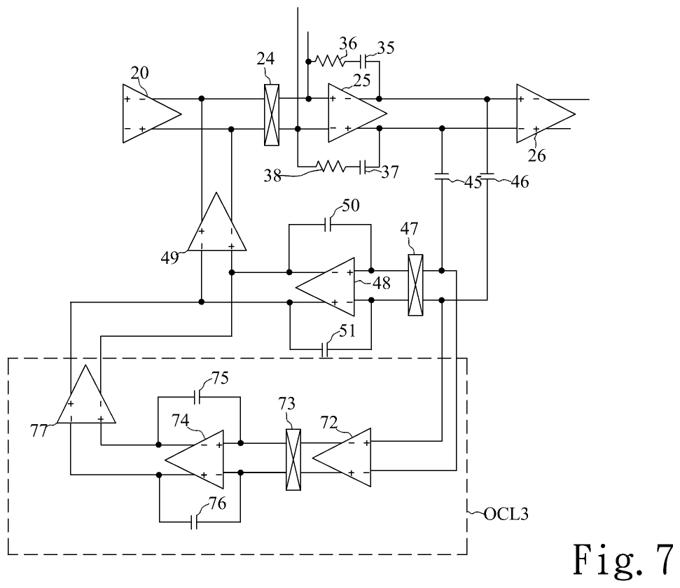

FIG. 7 is a diagram schematically illustrating an offset compensation loop according to a third embodiment of the invention. Please refer to FIG. 7. The multipath instrumentation amplifier further includes an offset compensation loop OCL3. The offset compensation loop OCL3 includes a third loop amplifier 72, a second loop chopper 73, a fourth loop amplifier 74, a fifth capacitor 75, a sixth capacitor 76, and a fifth loop amplifier 77. The third loop amplifier 72, the fourth loop amplifier 74, and the fifth loop amplifier 77 may be, but not limited to, transconductance amplifiers. The inverting input terminal of the third loop amplifier 72 is coupled to a node between the first capacitor 45 and the first loop chopper 47. The non-inverting input terminal of the third loop amplifier 72 is coupled to a node between the second capacitor 46 and the first loop chopper 47. The non-inverting input terminal and the inverting input terminal of the fourth loop amplifier 74 are respectively coupled to the inverting output terminal and the non-inverting output terminal of the third loop amplifier 72 through the second loop chopper 73. The fifth capacitor 75 is coupled between the inverting output terminal and the non-inverting input terminal of the fourth loop amplifier 74. The sixth capacitor 76 is coupled between the non-inverting output terminal and the inverting input terminal of the fourth loop amplifier 74. The non-inverting input terminal and the inverting input terminal of the fifth loop amplifier 77 are respectively coupled to the inverting output terminal and the non-inverting output terminal of the fourth loop amplifier 74. The inverting output terminal and the non-inverting output terminal of the fifth loop amplifier 77 are respectively coupled to the non-inverting input terminal and the inverting input terminal of the second loop amplifier 49.

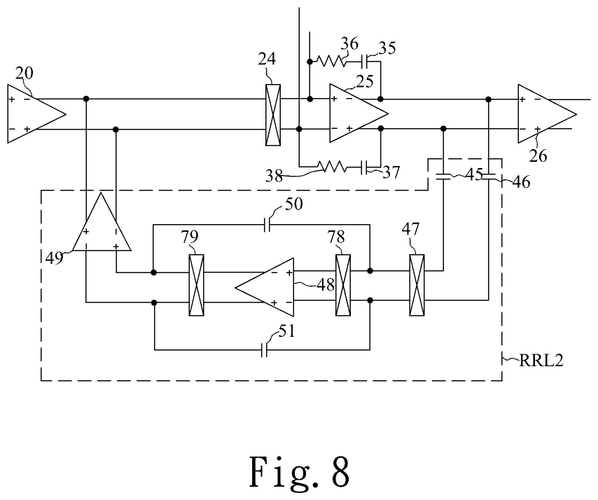

FIG. 8 is a diagram schematically illustrating a ripple reduction loop according to a second embodiment of the invention. Please refer to FIG. 8. In order to further reduce the ripple voltage across the voltage output terminals, compared with the embodiment of FIG. 4, the ripple reduction loop RRL2 of FIG. 8 further includes a first nested chopper 78 and a second nested chopper 79. One terminal of the third capacitor 50 is coupled to the non-inverting input terminal of the first loop amplifier 48 through the first nested chopper 78 and another end of the third capacitor 50 is coupled to the inverting output terminal of the first loop amplifier 48 through the second nested chopper 79. One terminal of the fourth capacitor 51 is coupled to the inverting input terminal of the first loop amplifier 48 through the first nested chopper 78 and another terminal of the fourth capacitor 51 is coupled to the non-inverting output terminal of the first loop amplifier 48 through the second nested chopper 79. The first nested chopper 78 and the second nested chopper 79 are used to reduce the affection caused by the offset voltage of the first loop amplifier 48. The embodiment of FIG. 8 may be combined with the embodiment of FIG. 4 or may be combined with the embodiment of FIG. 5, FIG. 6, or FIG. 7.

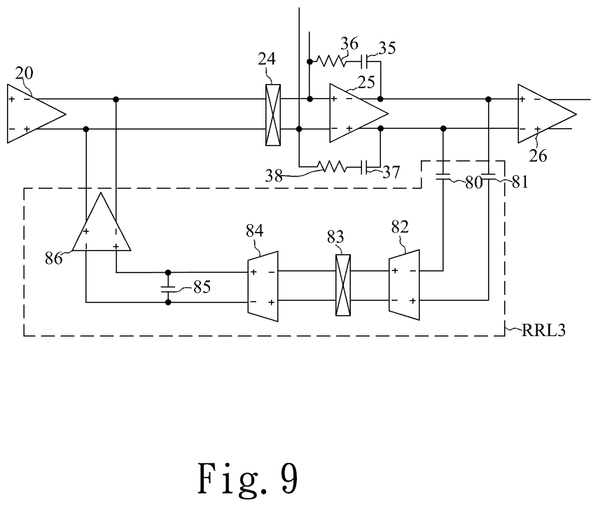

FIG. 9 is a diagram schematically illustrating a ripple reduction loop according to a third embodiment of the invention. Please refer to FIG. 9. Because the offset voltage of the ripple reduction loop RRL1 in FIG. 4 will generate additional residual ripples across the voltage output terminals that cannot be suppressed, a ripple reduction loop RRL3 is provided to replace the ripple reduction loop RRL1 in FIG. 4. The ripple reduction loop RRL3 includes a first capacitor 80, a second capacitor 81, a first buffer 82, a first loop chopper 83, a second buffer 84, a third capacitor 85, and a loop amplifier 86. The loop amplifier 86 may be, but not limited to, a transconductance amplifier. The inverting input terminal and the non-inverting input terminal of the first buffer 82 are respectively coupled to the inverting input terminal and the non-inverting input terminal of the fifth amplifier 26 through the first capacitor 80 and the second capacitor 81. The input terminals of the first loop chopper 83 are respectively coupled to the non-inverting output terminal and the inverting output terminal of the first buffer 82. The inverting input terminal and the non-inverting input terminal of the second buffer 84 are respectively coupled to the output terminals of the first loop chopper 83. The third capacitor 85 is coupled between the non-inverting output terminal and the inverting output terminal of the second buffer 84. The third capacitor 85 can integrate the received signal to avoid outputting the offset voltage of the ripple reduction loop RRL3. The non-inverting input terminal and the inverting input terminal of the loop amplifier 86 are respectively coupled to the non-inverting output terminal and the inverting output terminal of the second buffer 84. The non-inverting output terminal and the inverting output terminal of the loop amplifier 86 are respectively coupled to the non-inverting output terminal and the inverting output terminal of the third amplifier 20. The embodiment of FIG. 9 may be combined with the embodiment of FIG. 4 or may be combined with the embodiment of FIG. 5, FIG. 6 or FIG. 7.

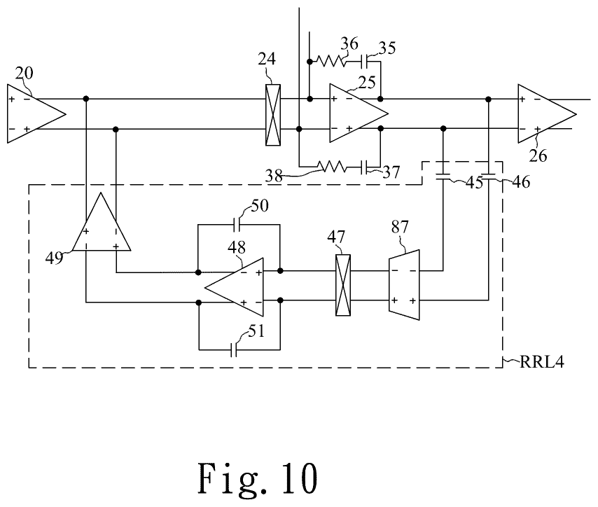

FIG. 10 is a diagram schematically illustrating a ripple reduction loop according to a fourth embodiment of the invention. Please refer to FIG. 10. In order to avoid deteriorating the ripple voltage across the voltage output terminals, compared with the embodiment of FIG. 4, the ripple reduction loop RRL4 of FIG. 10 further includes a buffer 87 whose inverting input terminal and non-inverting input terminal are respectively coupled to the first capacitor 45 and the second capacitor 46. The non-inverting output terminal and the inverting output terminal of the buffer 87 are respectively coupled to the input terminals of the first loop chopper 47. The embodiment of FIG. 10 may be combined with the embodiment of FIG. 4 or may be combined with the embodiment of FIG. 5, FIG. 6, or FIG. 7.

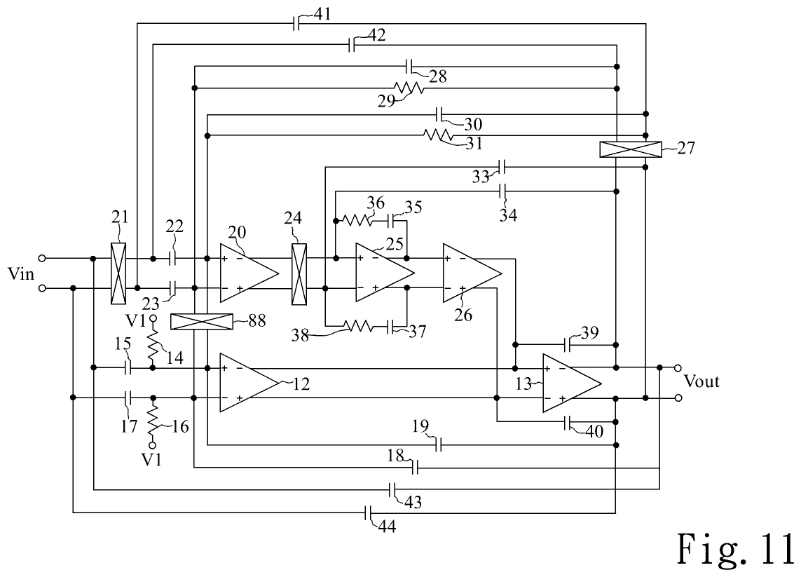

FIG. 11 is a diagram schematically illustrating a multipath instrumentation amplifier according to a second embodiment of the invention. Please refer to FIG. 11. Compared with the embodiment of FIG. 1, the multipath instrument amplifier of FIG. 11 further includes a fourth chopper 88 whose input terminals are respectively coupled to the non-inverting input terminal and the inverting input terminal of the third amplifier 20. The output terminals of the fourth chopper 88 are respectively coupled to the non-inverting input terminal and the inverting input terminal of the first amplifier 12. The fourth chopper 88 is used to rectify the feedback ripple across the voltage input terminals and compensate the offset voltage of the first amplifier 12 without auto-zeroing the first amplifier 12. The embodiment of FIG. 11 may be combined with the embodiment of FIG. 5, FIG. 6, FIG. 7, FIG. 8, FIG. 9 or FIG. 10.

According to the embodiments provided above, the multipath instrumentation amplifier employs the high-frequency amplifier circuit and uses the capacitors to form feedback paths and reduce the voltage ripple across the voltage output terminals, thereby increasing stability and accuracy.

The embodiments described above are only to exemplify the invention and not to limit the scope of the invention. Therefore, any equivalent modification or variation according to the shapes, structures, features, or spirit disclosed by the invention is to be also included within the scope of the invention.

What is claimed is:

1. A multipath instrumentation amplifier, having voltage input terminals and voltage output terminals, comprising:
a low-frequency amplifier circuit and a high-frequency amplifier circuit coupled between the voltage input terminals and the voltage output terminals, wherein the voltage input terminals are coupled to an input voltage, the low-frequency amplifier circuit and the high-frequency amplifier circuit are configured to amplify the input voltage and transmit the amplified input voltage to the voltage output terminals, the high-frequency amplifier circuit is configured to reduce voltage ripples across the voltage output terminals, and the high-frequency amplifier circuit comprises:
a first amplifier and a second amplifier, wherein an inverting output terminal and a non-inverting output terminal of the first amplifier are respectively coupled to a non-inverting input terminal and an inverting input terminal of the second amplifier, and a non-inverting output terminal and an inverting output terminal of the second amplifier are coupled to the voltage output terminals;
a first input resistor and a first input capacitor coupled in series between a first reference voltage and the voltage input terminal, and a node between the first input resistor and the first input capacitor is coupled to a non-inverting input terminal of the first amplifier;
a second input resistor and a second input capacitor coupled in series between the first reference voltage and the voltage input terminal, and a node between the second input resistor and the second input capacitor is coupled to an inverting input terminal of the first amplifier;
a first feedback capacitor coupled between the voltage output terminal and the inverting input terminal of the first amplifier; and
a second feedback capacitor coupled between the voltage output terminal and the non-inverting input terminal of the first amplifier.

2. The multipath instrumentation amplifier according to claim 1, wherein the low-frequency amplifier circuit includes:
a third amplifier;
a first chopper with input terminals thereof coupled to the voltage input terminals;
a third input capacitor and a fourth input capacitor, wherein output terminals of the first chopper are respectively coupled to a non-inverting input terminal and an inverting input terminal of the third amplifier through the third input capacitor and the fourth input capacitor;
a second chopper with input terminals respectively coupled to an inverting output terminal and a non-inverting output terminal of the third amplifier;
a fourth amplifier with a non-inverting input terminal thereof and an inverting input terminal thereof coupled to output terminals of the second chopper;
a fifth amplifier with a non-inverting input terminal thereof and an inverting input terminal thereof respectively coupled to an inverting output terminal and a non-inverting output terminal of the fourth amplifier, and an inverting output terminal and a non-inverting output terminal of the fifth amplifier are respectively coupled to the non-inverting input terminal and the inverting input terminal of the second amplifier;
a third chopper having a first input terminal and a second input terminal, wherein output terminals of the third chopper are coupled to the voltage output terminals;
a third feedback capacitor and a first feedback resistor coupled in parallel and coupled between the first input terminal of the third chopper and the inverting input terminal of the third amplifier; and
a fourth feedback capacitor and a second feedback resistor coupled in parallel and coupled between the second input terminal of the third chopper and the non-inverting input terminal of the third amplifier.

3. The multipath instrumentation amplifier according to claim 2, further comprising a resistor-capacitor (RC) circuit coupled to the inverting input terminals, the non-inverting input terminals, the inverting output terminals, and the non-inverting output terminals of the fourth amplifier and the second amplifier and configured to perform frequency compensation on the low-frequency amplifier circuit and the high-frequency amplifier circuit.

4. The multipath instrumentation amplifier according to claim 3, wherein the resistor-capacitor circuit is a low-pass filter.

5. The multipath instrumentation amplifier according to claim 3, wherein the resistor-capacitor circuit includes:
a first compensation capacitor coupled between the non-inverting output terminal of the second amplifier and the inverting input terminal of the fourth amplifier;
a second compensation capacitor coupled between the inverting output terminal of the second amplifier and the non-inverting input terminal of the fourth amplifier;
a third compensation capacitor and a first compensation resistor coupled in series and coupled between the inverting output terminal and the non-inverting input terminal of the fourth amplifier;
a fourth compensation capacitor and a second compensation resistor coupled in series and coupled between the non-inverting output terminal and the inverting input terminal of the fourth amplifier;
a fifth compensation capacitor coupled between the non-inverting input terminal and the inverting output terminal of the second amplifier; and
a sixth compensation capacitor is coupled between the inverting input terminal and the non-inverting output terminal of the second amplifier.

6. The multipath instrumentation amplifier according to claim 2, further comprising:
a first loop capacitor with one terminal thereof coupled to a node between the first chopper and the fourth input capacitor, and another terminal of the first loop capacitor is coupled to the second input terminal of the third chopper; and
a second loop capacitor with one terminal thereof coupled to a node between the first chopper and the third input capacitor, and another terminal of the second loop capacitor is coupled to the first input terminal of the third chopper.

7. The multipath instrumentation amplifier according to claim 6, further comprising:
a third loop capacitor with one terminal thereof coupled to a node between the voltage input terminal and the first input capacitor, and another terminal of the third loop capacitor is coupled to a node between the voltage output terminal and the inverting output terminal of the second amplifier; and
a fourth loop capacitor with one terminal thereof coupled to a node between the voltage input terminal and the second input capacitor, and another terminal of the fourth loop capacitor is coupled to a node between the voltage output terminal and the non-inverting output terminal of the second amplifier.

8. The multipath instrumentation amplifier according to claim 2, further comprising:
a first capacitor and a second capacitor;
a first loop chopper with input terminals respectively coupled to the inverting input terminal and the non-inverting input terminal of the fifth amplifier through the first capacitor and the second capacitor;
a first loop amplifier with a non-inverting input terminal thereof and an inverting input terminal thereof coupled to output terminals of the first loop chopper;
a second loop amplifier with a non-inverting input terminal thereof and an inverting input terminal thereof respectively coupled to an inverting output terminal and a non-inverting output terminal of the first loop amplifier, and a non-inverting output terminal and an inverting output terminal of the second loop amplifier are respectively coupled to the inverting output terminal and the non-inverting output terminal of the third amplifier;
a third capacitor coupled between the non-inverting input terminal and the inverting output terminal of the first loop amplifier; and
a fourth capacitor coupled between the inverting input terminal and the non-inverting output terminal of the first loop amplifier.

9. The multipath instrumentation amplifier according to claim 8, further comprising:
a first auto-zeroing capacitor;
a first switch coupling the first auto-zeroing capacitor to the inverting input terminal of the first loop amplifier or a second reference voltage;
a second auto-zeroing capacitor;
a second switch coupling the second auto-zeroing capacitor to the non-inverting input terminal of the first loop amplifier or the second reference voltage;
a third loop amplifier with a non-inverting input terminal thereof coupled to the first switch through the first auto-zeroing capacitor, and an inverting input terminal of the third loop amplifier is coupled to the second switch through the second auto-zeroing capacitor;
a fourth loop amplifier;
a third switch coupling an inverting output terminal of the third loop amplifier to a non-inverting input terminal of the fourth loop amplifier or the non-inverting input terminal of the third loop amplifier;
a fourth switch coupling a non-inverting output terminal of the third loop amplifier to an inverting input terminal of the fourth loop amplifier or the inverting input terminal of the third loop amplifier;
a fifth capacitor coupled between an inverting output terminal and the non-inverting input terminal of the fourth loop amplifier;
a sixth capacitor coupled between a non-inverting output terminal and the inverting input terminal of the fourth loop amplifier; and
a fifth loop amplifier with a non-inverting input terminal thereof and an inverting input terminal thereof respectively coupled to the inverting output terminal and the non-inverting output terminal of the fourth loop amplifier, and an inverting output terminal and a non-inverting output terminal of the fifth loop amplifier are respectively coupled to the non-inverting input terminal and the inverting input terminal of the second loop amplifier.

10. The multipath instrumentation amplifier according to claim 8, further comprising:
a first auto-zeroing capacitor;
a first switch coupling the first auto-zeroing capacitor to the inverting input terminal of the first loop amplifier or a second reference voltage;
a second auto-zeroing capacitor;
a second switch coupling the second auto-zeroing capacitor to the non-inverting input terminal of the first loop amplifier or the second reference voltage;
a third loop amplifier with a non-inverting input terminal thereof coupled to the first switch through the first auto-zeroing capacitor, and an inverting input terminal of the third loop amplifier is coupled to the second switch through the second auto-zeroing capacitor;
a fourth loop amplifier with an inverting output terminal thereof and a non-inverting output terminal thereof respectively coupled to the inverting input terminal and the non-inverting input terminal of the second loop amplifier;
a third switch coupling an inverting output terminal of the third loop amplifier to a non-inverting input terminal of the fourth loop amplifier or the non-inverting input terminal of the third loop amplifier;
a fourth switch coupling a non-inverting output terminal of the third loop amplifier to an inverting input terminal of the fourth loop amplifier or the inverting input terminal of the third loop amplifier; and
a fifth capacitor coupled between the inverting input terminal and the non-inverting input terminal of the fourth loop amplifier.

11. The multipath instrumentation amplifier according to claim 8, further comprising:
a third loop amplifier with an inverting input terminal thereof coupled to a node between the first capacitor and the first loop chopper, and a non-inverting input terminal of the third loop amplifier is coupled to a node between the second capacitor and the first loop chopper;
a second loop chopper and a fourth loop amplifier, wherein a non-inverting input terminal and an inverting input terminal of the fourth loop amplifier are respectively coupled to an inverting output terminal and a non-inverting output terminal of the third loop amplifier through the second loop chopper;
a fifth capacitor coupled between an inverting output terminal and the non-inverting input terminal of the fourth loop amplifier;
a sixth capacitor coupled between a non-inverting output terminal and the inverting input terminal of the fourth loop amplifier; and
a fifth loop amplifier with a non-inverting input terminal thereof and an inverting input terminal thereof respectively coupled to the inverting output terminal and the non-inverting output terminal of the fourth loop amplifier, and an inverting output terminal and a non-inverting output terminal of the fifth loop amplifier are respectively coupled to the non-inverting input terminal and the inverting input terminal of the second loop amplifier.

12. The multipath instrumentation amplifier according to claim 8, further comprising:
a first nested chopper; and
a second nested chopper, wherein one terminal of the third capacitor is coupled to the non-inverting input terminal of the first loop amplifier through the first nested chopper, another terminal of the third capacitor is coupled to the inverting output terminal of the first loop amplifier through the second nested chopper, one terminal of the fourth capacitor is coupled to the inverting input terminal of the first loop amplifier through the first nested chopper, another terminal of the fourth capacitor is coupled to the non-inverting output terminal of the first loop amplifier through the second nested chopper.

13. The multipath instrumentation amplifier according to claim 2, further comprising:
a first capacitor and a second capacitor;
a first buffer with an inverting input terminal thereof and a non-inverting input terminal thereof respectively coupled to the inverting input terminal and the non-inverting input terminal of the fifth amplifier through the first capacitor and the second capacitor;
a first loop chopper with input terminals thereof respectively coupled to a non-inverting output terminal and an inverting output terminal of the first buffer;
a second buffer with an inverting input terminal thereof and a non-inverting input terminal thereof respectively coupled to output terminals of the first loop chopper;
a third capacitor coupled between a non-inverting output terminal and an inverting output terminal of the second buffer; and
a loop amplifier with a non-inverting input terminal thereof and an inverting input terminal thereof respectively coupled to the non-inverting output terminal and the inverting output terminal of the second buffer, and a non-inverting output terminal and an inverting output terminal of the loop amplifier are respectively coupled to the non-inverting output terminal and the inverting output terminal of the third amplifier.

14. The multipath instrumentation amplifier according to claim 8, further comprising a buffer with an inverting input terminal thereof and a non-inverting input terminal thereof respectively coupled to the first capacitor and the second capacitor, and a non-inverting output terminal and an inverting output terminal of the buffer are respectively coupled to the input terminals of the first loop chopper.

15. The multipath instrumentation amplifier according to claim 2, further comprising a fourth chopper with input terminals respectively coupled to the non-inverting input terminal and the inverting input terminal of the third amplifier, and output terminals of the fourth chopper are respectively coupled to the non-inverting input terminal and the inverting input terminal of the first amplifier.
